(19) United States
(12) Patent Application Publication
(10) Pub. No.: US 2020/0203917 A1
(43) Pub. Date: Jun. 25, 2020

(54) OPTICAL MODULE

(71) Applicant: FURUKAWA ELECTRIC CO., LTD., Tokyo (JP)

(72) Inventors: Kazuki YAMAOKA, Tokyo (JP); Maiko ARIGA, Tokyo (JP); Kazuaki KIYOTA, Tokyo (JP); Yusuke INABA, Tokyo (JP)

(73) Assignee: FURUKAWA ELECTRIC CO., LTD., Tokyo (JP)

(21) Appl. No.: 16/807,231

(22) Filed: Mar. 3, 2020

Related U.S. Application Data
(63) Continuation of application No. PCT/JP2018/033104, filed on Sep. 6, 2018.

(30) Foreign Application Priority Data
Sep. 8, 2017 (JP) 2017-173521

(51) Int. Cl. H01S 5/00; H01S 5/022; H01S 5/40

(52) U.S. Cl. CPC H01S 5/0064; H01S 5/40; H01S 5/022

(57) ABSTRACT

An optical module includes a first optical function device that has an emission end and emits a light from the emission end; a second optical function device that has an entry end and an emission end, amplifies the light entering the entry end, and emits the amplified light from the emission end, wherein the light is emitted from the emission end of the first optical function device and enters the entry end; a first optical non-reciprocal device that is arranged between the emission end of the first optical function device and the entry end of the second optical function device, transmits a light in a first direction from the emission end of the first optical function device toward the entry end of the second optical function device, and blocks or attenuates a light in a second direction opposite to the first direction; and a second optical non-reciprocal device that is arranged on the emission end side of the second optical function device, transmits a light in a third direction outward from the emission end of the second optical function device, and blocks or attenuates a light in a fourth direction opposite to the third direction.

### CROSS-REFERENCE TO RELATED APPLICATIONS

This application is a continuation application of International Application No. PCT/JP2018/033104, filed Sep. 6, 2018, which claims the benefit of Japanese Patent Application No. 2017-173521, filed Sep. 8, 2017. The contents of the aforementioned applications are incorporated herein by reference in their entireties.

### TECHNICAL FIELD

The present invention relates to an optical module having an optical function device that amplifies light.

### BACKGROUND ART

In recent years, in laser modules widely used in the field of optical communication or the like, there is a demand for increase in output power, and the calorific values in such a laser device and an optical amplifier have increased. To address such heat generation or the like of the device, a laser module in which a laser device and an optical amplifier are separately provided is proposed in addition to a laser module in which a laser device and an optical amplifier are integrated on one chip (Patent Literatures 1 to 3).

Patent Literature 1 discloses a semiconductor laser module having a semiconductor laser device having a semiconductor laser and a semiconductor optical device having a semiconductor optical amplifier that amplifies a laser light output from the semiconductor laser device. The semiconductor laser module disclosed in Patent Literature 1 has a first support member on which the semiconductor laser device is placed, a first temperature adjustment device that adjusts the temperature of the first support member, a second support member on which the semiconductor optical device is placed, and a second temperature adjustment device that adjusts the temperature of the second support member.

Patent Literature 2 discloses a semiconductor laser module having a semiconductor laser device that outputs a signal light, a semiconductor optical amplifier device that amplifies the signal light output from the semiconductor laser device, a carrier used for fixing these devices, and a thermoelectric cooling device used for fixing the carrier.

Patent Literature 3 discloses a wavelength tunable stabilized laser having a laser that can oscillate a light of a plurality of wavelengths, a control unit that controls laser oscillation wavelengths, and an optical amplifier unit that amplifies a laser light to be extracted to the outside.

### CITATION LIST

### Patent Literature

Patent Literature 1: Japanese Patent No. 5567226
Patent Literature 2: Japanese Patent Application Laid-Open No. 2005-19820
Patent Literature 3: Japanese Patent Application Laid-Open No. 2001-251013

### SUMMARY OF INVENTION

### Technical Problem

Conventionally, in a laser module in which a laser device and an optical amplifier are separately provided, an optical isolator is used in order to prevent a return light to the laser device. Patent Literature 1 discloses that an optical isolator is arranged between the laser device and the semiconductor optical amplifier device, and entry of a return light to the laser device is prevented by the optical isolator. Further, Patent Literature 2 discloses that an optical isolator is provided between a semiconductor laser device and a semiconductor optical amplifier device to prevent a return light to the semiconductor laser device. Further, Patent Literature 3 discloses that an isolator is provided on the emission side of a semiconductor optical amplifier.

It is however difficult to sufficiently suppress deterioration of module characteristics caused by a return light due to reflection or an amplified spontaneous emission (ASE) light in an optical amplifier only by arranging an optical isolator between a laser device and an optical amplifier or arranging an optical isolator on the emission side of an optical amplifier as in a conventional manner.

The present invention has been made in view of the above and intends to provide an optical module that can sufficiently suppress deterioration of characteristics and obtain high optical output power.

### Solution to the Problem

According to one aspect of the present invention, provided is an optical module that includes a first optical function device that has an emission end and emits a light from the emission end; a second optical function device that has an entry end and an emission end, amplifies the light entering the entry end, and emits the amplified light from the emission end, wherein the light is emitted from the emission end of the first optical function device and enters the entry end; a first optical non-reciprocal device that is arranged between the emission end of the first optical function device and the entry end of the second optical function device, transmits a light in a first direction from the emission end of the first optical function device toward the entry end of the second optical function device, and blocks or attenuates a light in a second direction that is a direction opposite to the first direction; and a second optical non-reciprocal device that is arranged on the emission end side of the second optical function device, transmits a light in a third direction outward from the emission end of the second optical function device, and blocks or attenuates a light in a fourth direction that is a direction opposite to the third direction.

### Advantageous Effects of Invention

According to the present invention, deterioration of characteristics can be sufficiently suppressed, and high optical output power can be obtained.

### BRIEF DESCRIPTION OF DRAWINGS

FIG. 1 is a schematic diagram illustrating an optical module according to a first embodiment of the present invention.

FIG. 2 is a graph illustrating one example in which influence of an inflow of an ASE light from a semiconductor optical amplifier on characteristics of a semiconductor laser device is calculated.

FIG. 3 is a graph illustrating one example in which influence of a return light due to reflection on characteristics of the semiconductor optical amplifier is calculated.

FIG. 4 is a graph illustrating a relationship between isolation of a first optical isolator and a spectral linewidth of a laser light of the semiconductor laser device in the optical module according to the first embodiment of the present invention.

FIG. 5 is a graph illustrating a relationship between isolation of a second optical isolator and optical output in the optical module according to the first embodiment of the present invention.

FIG. 6 is a graph illustrating one example of a relationship between the optical output of the optical module and a drive current of the semiconductor optical amplifier according to the first embodiment of the present invention.

FIG. 7 is a graph illustrating one example of a relationship between a polarization extinction ratio of the optical module and a drive current of the semiconductor optical amplifier according to the first embodiment of the present invention.

FIG. 8 is a schematic diagram illustrating an optical module according to a second embodiment of the present invention.

FIG. 9 is a schematic diagram illustrating an optical module according to a third embodiment of the present invention.

FIG. 10A is a schematic diagram illustrating arrangement of devices in an optical module according to a fourth embodiment of the present invention.

FIG. 10B is a schematic diagram illustrating arrangement of devices in an optical module according to the fourth embodiment of the present invention.

FIG. 11A is a schematic diagram illustrating a polarization independent optical isolator used for an optical module according to a fifth embodiment of the present invention.

FIG. 11B is a schematic diagram illustrating the polarization independent optical isolator used for an optical module according to the fifth embodiment of the present invention.

FIG. 12 is a schematic diagram illustrating an optical module according to a sixth embodiment of the present invention.

### DESCRIPTION OF EMBODIMENTS

### First Embodiment

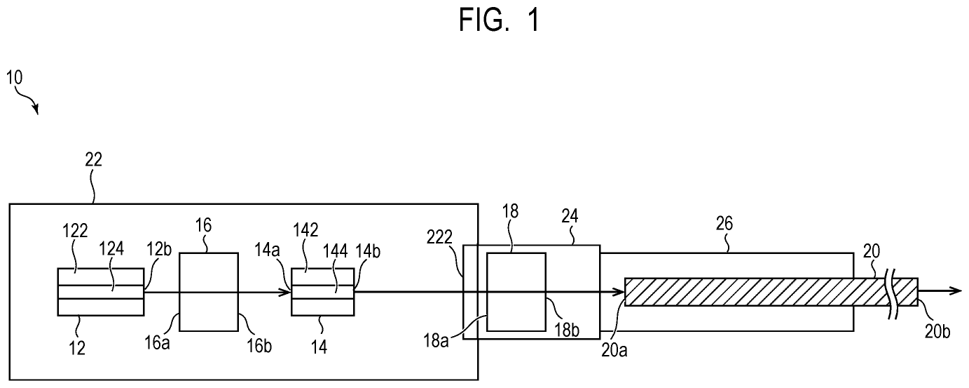

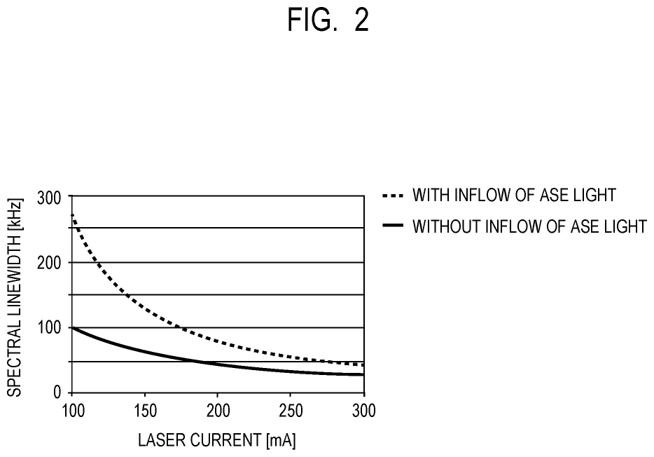

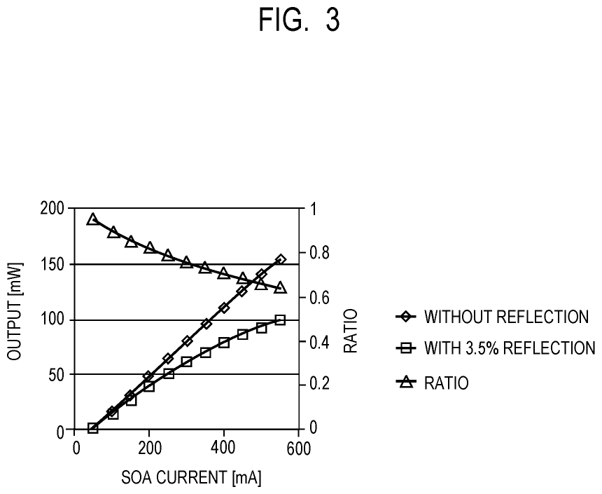

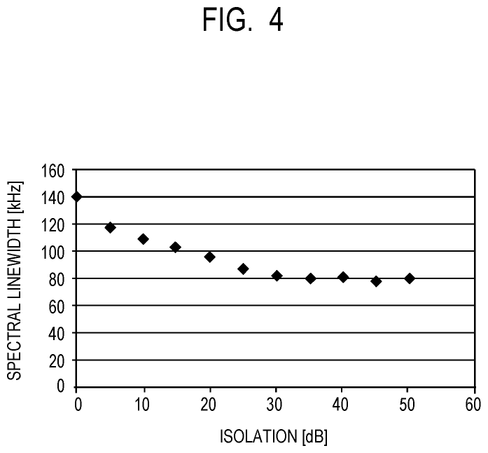

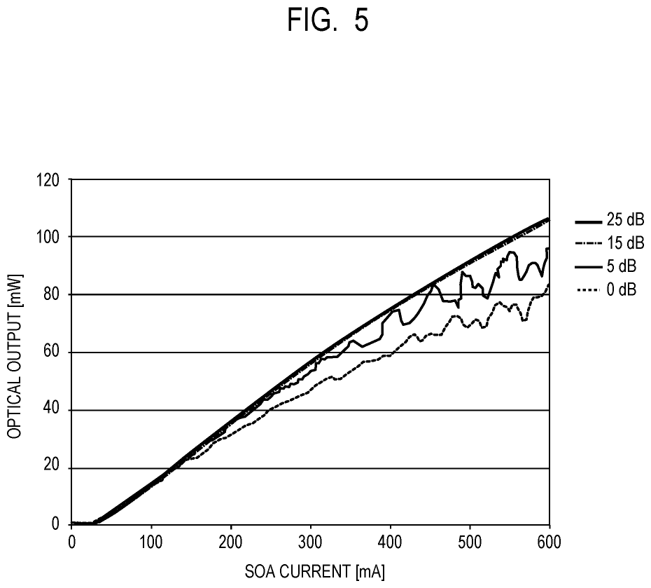

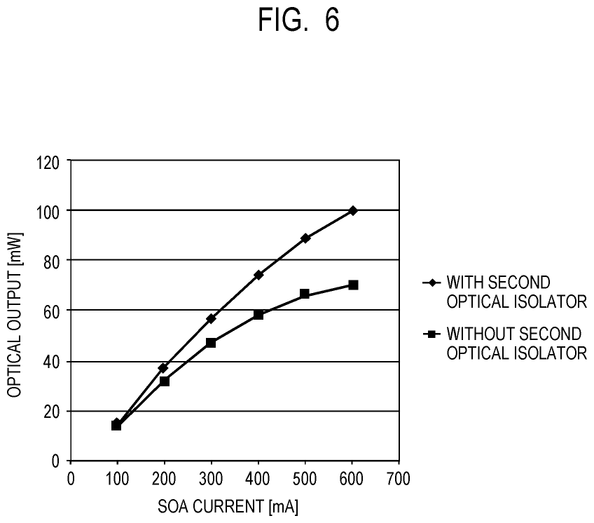

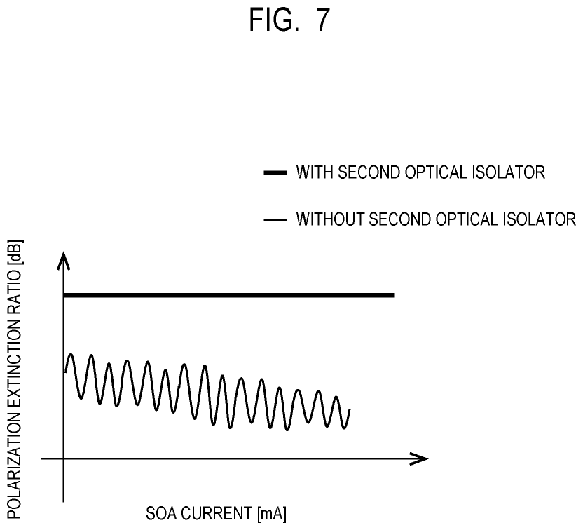

An optical module according to a first embodiment of the present invention will be described with reference to FIG. 1 to FIG. 7. FIG. 1 is a schematic diagram illustrating an optical module according to the present embodiment. FIG.2 is a graph illustrating one example in which influence of an inflow of an ASE light from a semiconductor optical amplifier on characteristics of a semiconductor laser device is calculated. FIG. 3 is a graph illustrating one example in which influence of a return light due to reflection on characteristics of the semiconductor optical amplifier is calculated. FIG. 4 is a graph illustrating a relationship between isolation of a first optical isolator and a spectral linewidth of a laser light of the semiconductor laser device in the optical module according to the present embodiment. FIG. 5 is a graph illustrating a relationship between isolation of a second optical isolator and optical output in the optical module according to the present embodiment. FIG. 6 is a graph illustrating one example of a relationship between optical output of the optical module according to the present embodiment and a drive current of the semiconductor optical amplifier. FIG. 7 is a graph illustrating one example of a relationship between a polarization extinction ratio of the optical module according to the present embodiment and a drive current of the semiconductor optical amplifier.

First, the configuration of the optical module according to the present embodiment will be described with reference to FIG. 1.

As illustrated in FIG. 1, an optical module 10 according to the present embodiment has a semiconductor laser device 12, a semiconductor optical amplifier (SOA) 14, a first optical isolator 16, a second optical isolator 18, and an optical fiber 20. The optical module 10 according to the present embodiment further has a package 22, a holding member 24, and a tubular member 26. The package 22 accommodates the semiconductor laser device 12, the SOA 14, and the first optical isolator 16. The holding member 24 holds the second optical isolator 18. The tubular member 26 holds the optical fiber 20.

The package 22 is a casing that accommodates the semiconductor laser device 12, the SOA 14, and the first optical isolator 16 therein. The package 22 is made of a metal, for example, and is hermitically sealed with the inside thereof being filled with an inert gas, a nitrogen gas, or the like. The package 22 is not particularly limited, and a butterfly type or a dual inline type may be used, for example.

The semiconductor laser (laser diode) device 12 is a first optical function device that functions as a light emitting device that has an emission end 12b and emits a laser light from the emission end 12b. The semiconductor laser device 12 is not particularly limited, and a distributed feedback (DFB) laser may be used, for example.

The semiconductor laser device 12 has a substrate 122 and a laser oscillation unit 124 formed on the substrate 122. The substrate 122 is arranged on a temperature adjustment device (not illustrated) such as a Peltier device used for cooling the semiconductor laser device 12 and adjusting the temperature. The laser oscillation unit 124 is an optical waveguide having stripe mesa structure including an active layer and generates a laser light when electric power is supplied. One end of the laser oscillation unit 124 corresponds to the emission end 12b. Note that the configuration of the semiconductor laser device 12 is not limited thereto, and various configurations may be employed.

The SOA 14 has an entry end 14a and an emission end 14b and is arranged such that a laser light emitted from the emission end 12b of the semiconductor laser device 12 enters the entry end 14a. The SOA 14 is a second optical function device that functions as an optical amplifier device that amplifies a laser light that has entered the entry end 14a and emits the amplified laser light from the emission end 14b.

The SOA 14 is provided separately from the semiconductor laser device 12 and has a substrate 142 and an optical amplifier unit 144 formed on the substrate 142. The substrate 142 is arranged on a temperature adjustment device (not illustrated) such as a Peltier device used for cooling the SOA 14 and adjusting the temperature. The optical amplifier unit 144 is an optical waveguide having stripe mesa structure including an active layer and amplifies a laser light when electric power is supplied. One end of the optical amplifier unit 144 corresponds to the entry end 14a. The other end of the optical amplifier unit 144 corresponds to the emission end 14b. Note that the configuration of the SOA 14 is not limited thereto, and various configurations may be used.

The first optical isolator 16 is arranged between the emission end 12b of the semiconductor laser device 12 and the entry end 14a of the SOA 14. The first optical isolator 16 is a first optical non-reciprocal device that has non-reciprocity, transmits a laser light in a first direction from the emission end 12b of the semiconductor laser device 12 toward the entry end 14a of the SOA 14, and blocks or attenuates a laser light in a second direction that is a direction opposite to the first direction. The first optical isolator 16 has an entry end 16a that receives a laser light emitted from the emission end 12b of the semiconductor laser device 12 and an emission end 16b that transmits and emits a laser light toward the entry end 14a of the SOA 14.

While the first optical isolator 16 is not particularly limited, when the semiconductor laser device 12 emits a linearly polarized laser light, for example, a polarization dependent optical isolator may be used. In such a case, the first optical isolator 16 has two polarizers whose transmission axes are inclined at 45 degree relative to each other, a Faraday rotator that is inserted between the two polarizers and has a Faraday rotation angle of 45 degree, and a magnet that applies a magnetic field to the Faraday rotator. Note that a semiconductor optical isolator may also be used as the first optical isolator 16.

A window 222 from which a laser light amplified by the SOA 14 and emitted from the emission end 14b is emitted is provided on a side wall of the package 22. The holding member 24 is provided on the side wall of the package 22 on which the window 222 is provided. The holding member 24 is another casing in which optical elements such as the second optical isolator 18, a lens (not illustrated), or the like is accommodated and held.

The tubular member 26 is provided at the end opposite to the package 22 of the holding member 24. The optical fiber 20 is inserted and fixed inside the tubular member 26. The optical fiber 20 fixed inside the tubular member 26 has the entry end 20a directed to the holding member 24 side. A portion of the optical fiber 20 on the emission end 20b side protrudes out of the tubular member 26.

The second optical isolator 18 is held inside the holding member 24 and arranged on the emission end 14b side of the SOA 14, that is, arranged between the emission end 14b of the SOA 14 and the entry end 20a of the optical fiber 20. The second optical isolator 18 is a second optical non-reciprocal device that has non-reciprocity, transmits a laser light in a third direction from the emission end 14b of the SOA 14 toward the entry end 20a of the external optical fiber 20, and blocks or attenuates a laser light in a fourth direction that is a direction opposite to the third direction. The second optical isolator 18 has an entry end 18a that receives a laser light emitted from the emission end 14b of the SOA 14 and an emission end 18b that transmits and emits a laser light toward the entry end 20a of the optical fiber 20.

While the second optical isolator 18 is not particularly limited, a polarization dependent optical isolator may be used, for example, in the same manner as the first optical isolator 16. Note that a semiconductor optical isolator may also be used as the second optical isolator 18.

The optical fiber 20 is fixed inside the tubular member such that a laser light transmitting through the second optical isolator 18 enters the entry end 20a. The entry end 20a of the optical fiber 20 is optically connected to the emission end 14b of the SOA 14. Although not particularly limited, the optical fiber 20 is a single-mode optical fiber, for example. Further, the optical fiber 20 may be a polarization maintaining optical fiber having a polarization maintaining ability such as a polarization-maintaining and absorption-reducing (PANDA) fiber, a bow-tie fiber, an elliptical core optical fiber, or the like.

As described above, the optical module 10 according to the present embodiment in which the semiconductor laser device 12 that is a light emitting device and the SOA 14 that is an optical amplifier device are provided so as to be separated from each other is formed.

In the optical module 10 according to the present embodiment, a laser light emitted from the emission end 12b of the semiconductor laser device 12 enters the entry end 16a of the first optical isolator 16. The laser light that has entered the entry end 16a of the first optical isolator 16 transmits through the first optical isolator 16 and is emitted from the emission end 16b. The laser light emitted from the emission end 16b of the first optical isolator 16 enters the entry end 14a of the SOA 14. The laser light that has entered the entry end 14a of the SOA 14 is amplified by the SOA 14 and emitted from the emission end 14b. The laser light amplified and emitted from the emission end 14b of the SOA 14 enters the entry end 18a of the second optical isolator 18. The laser light that has entered the entry end 18a of the second optical isolator 18 transmits through the second optical isolator 18 and is emitted from the emission end 18b. The laser light emitted from the emission end 18b of the second optical isolator 18 enters the entry end 20a of the optical fiber 20. The laser light that has entered the entry end 20a of the optical fiber 20 propagates inside the optical fiber 20 and is emitted from the emission end 20b as an output light of the optical module 10.

While the optical module 10 outputs an output light as described above, the first optical isolator 16 blocks or attenuates a light in the direction opposite to the direction of the laser light transmitting through the first optical isolator 16, that is, a return light due to reflection or an ASE light from the SOA 14. Further, the second optical isolator 18 blocks or attenuates a light in the direction opposite to the direction of the laser light transmitting through the second optical isolator 18, that is, a return light due to reflection.

Note that an element such as an optical element such as a mirror, a lens, a beam splitter, or the like may be arranged between devices of the semiconductor laser device 12, the first optical isolator 16, the SOA 14, the second optical isolator 18, and the optical fiber 20 in the optical module 10.

As described above, in the optical module 10 according to the present embodiment, the first optical isolator 16 is arranged between the emission end 12b of the semiconductor laser device 12 and the entry end 14a of the SOA 14, and the second optical isolator 18 is arranged on the emission end 14b side of the SOA 14. With the first optical isolator 16 and the second optical isolator 18 being arranged in such a way, the optical module 10 according to the present embodiment can suppress deterioration of characteristics of both devices of the semiconductor laser device 12 and the SOA 14, and high optical output power can be obtained. This feature will be described below in detail.

Conventionally, in a module in which a semiconductor laser device that emits a laser light and an SOA that amplifies and outputs a laser light are separated from each other, an optical isolator is arranged either between the emission end of the semiconductor laser device and the entry end of the SOA or only on the emission end side of the SOA.

First, in a configuration in which an optical isolator is arranged only on the emission end side of the SOA, a reflection light at the entry end of the SOA returns to the semiconductor laser device and enters the semiconductor laser device. Further, an ASE light generated in the SOA returns to the semiconductor laser device and enters the semiconductor laser device. As a result of the reflection light or the ASE light at the entry end of the SOA returning to the semiconductor laser device and entering the semiconductor laser device in such a way, noise occurs in the semiconductor laser device, and laser characteristics deteriorate.

FIG. 2 is a graph illustrating one example in which influence of an inflow of the ASE light from the SOA on characteristics of the semiconductor laser device is calculated. In the graph illustrated in FIG. 2, the horizontal axis represents a laser current that is a drive current of the semiconductor laser device, and the vertical axis represents a spectral linewidth of a laser light emitted from the semiconductor laser device. FIG. 2 illustrates a case where there is an inflow of the ASE light from the SOA into the semiconductor laser device and a case where there is no inflow of the ASE light from the SOA into the semiconductor laser device.

As illustrated in FIG. 2, when there is an inflow of an ASE light from the SOA to the semiconductor laser device, the spectral linewidth of the laser light increases and the laser characteristics deteriorate over the entire range of the laser current compared to a case where there is no inflow of an ASE light.

On the other hand, in a configuration in which an optical isolator is arranged only between the emission end of the semiconductor laser device and the entry end of the SOA, a light reflected on the end face of a connector or the like returns to the SOA and enters the SOA. As a result of the reflected light returning to the SOA and entering the SOA in such a way, in the SOA, output of the SOA is reduced due to a mechanism different from the characteristics deterioration of the semiconductor laser device described above.

FIG. 3 is a graph illustrating one example in which influence of a return light due to reflection on characteristics of the SOA is calculated. In the graph illustrated in FIG. 3, the horizontal axis represents an SOA current that is a drive current of the SOA, and the left vertical axis represents the output of the SOA. FIG. 3 illustrates a case where there is no reflection and a case where there is 3.5% reflection. Further, FIG. 3 illustrates a ratio of the output when there is a reflection to the output when there is no reflection. The right vertical axis of the graph illustrated in FIG. 3 represents the ratio.

According to the calculation examples illustrated in FIG. 3, when there is 3.5% reflection, the output of the SOA decreases at a rate larger than the reflectance thereof. The output of the SOA decreases by 40% or less at the maximum. The reason why the output of the SOA is reduced in such a way by the return light due to reflection is that, when there is a light that enters the emission end of the SOA as a return light due to reflection and propagates toward the rear of the SOA to travel to the entry end of the SOA, the SOA amplifies the light propagating toward the rear. When carriers injected into the SOA are consumed for amplifying the light propagating toward the rear of the SOA, the injected carriers that can be used for amplifying the light propagating forward that is originally intended to be amplified by the SOA are reduced. As a result, the efficiency of the SOA deteriorates, and the output of the SOA decreases. While FIG. 3 illustrates the case of 3.5% reflection, a change in the reflection rate results in a change in the output of the SOA. A change in the output of the SOA causes a problem of difficulty in evaluation of the characteristics of the optical module because of Fresnel reflection or the like when an output light is output to the air from the optical fiber through which the output light propagates.

With respect to the problem described above, in the optical module 10 according to the present embodiment, the first optical isolator 16 can block or attenuate the return light due to reflection or the ASE light from the SOA 14, and thereby deterioration of the characteristics of the semiconductor laser device 12 as described above can be suppressed. Further, the second optical isolator 18 can block or attenuate the return light due to reflection, and thereby deterioration of characteristics of the SOA 14 as described above can be suppressed. Therefore, according to the present embodiment, deterioration of characteristics of the optical module 10 can be suppressed, and high optical output power can be obtained.

The isolation of the first optical isolator 16 can be preferably set as described below.

FIG. 4 is a graph illustrating a relationship between isolation of the first optical isolator 16 and a spectral linewidth of the laser light of the semiconductor laser device 12. In the graph illustrated in FIG. 4, the horizontal axis represents the isolation of the first optical isolator 16, and the vertical axis represents the spectral linewidth of a laser light of the semiconductor laser device 12.

According to the graph illustrated in FIG. 4, when the isolation of the first optical isolator 16 is from 0 dB to 30 dB, as the isolation of the first optical isolator 16 becomes higher, the spectral linewidth of the laser light of the semiconductor laser device 12 decreases. When the isolation of the first optical isolator 16 is higher than or equal to 30 dB, the spectral linewidth of the laser light of the semiconductor laser device 12 is substantially constant regardless of the isolation level.

Therefore, to stably drive the semiconductor laser device 12 and obtain a laser light having a narrow spectral linewidth, it is preferable to set the isolation of the first optical isolator 16 to be higher than or equal to 30 dB. Note that the upper limit of the isolation of the first optical isolator 16 is not particularly limited, and it is practical that the upper limit is lower than or equal to 80 dB in terms of industrial availability or the like.

On the other hand, the isolation of the second optical isolator 18 can be preferably set as further described below.

FIG. 5 is a graph illustrating a relationship between isolation of the second optical isolator 18 and optical output. In the graph illustrated in FIG. 5, the horizontal axis represents the SOA current that is a drive current of the SOA 14, and the vertical axis represents the optical output of the optical module 10. Note that the optical output of the optical module 10 corresponds to the output of a laser light at the emission end 20b of the optical fiber 20. FIG. 5 illustrates cases where the isolations are 0 dB, 5 dB, 15 dB, and 25 dB, respectively.

According to the graph illustrated in FIG. 5, when the isolation of the second optical isolator 18 is from 0 dB to 15 dB, as the isolation of the second optical isolator 18 becomes higher, the optical output of the optical module 10 increases. When the isolation of the second optical isolator 18 is higher than or equal to 15 dB, the optical output of the optical module 10 with respect to the same SOA current is substantially constant regardless of the isolation level. Further, when the isolation of the second optical isolator 18 is 0 dB and 5 dB, fluctuation in which the optical output of the optical module 10 significantly increases or decreases due to a change in the SOA current is found, and the optical output is unstable. On the other hand, when the isolation of the second optical isolator 18 is 15 dB and 25 dB, such fluctuation is not found in the optical output of the optical module 10, and the optical output is stable.

Therefore, to stably drive the SOA 14 and obtain a high optical output power, it is preferable to set the isolation of the second optical isolator 18 to be higher than or equal to dB. Further, when the optical output is monitored by splitting the optical output, and when a weak light is monitored by splitting a faint light, since even an small change in the optical output may cause influence, it is more preferable to set the isolation of the second optical isolator 18 to be higher than or equal to 30 dB. Note that the upper limit of the isolation of the second optical isolator 18 is not particularly limited, and in the same manner as the first optical isolator 16, it is practical that the upper limit is lower than or equal to 80 dB in terms of industrial availability.

FIG. 6 is a graph illustrating one example of a relationship between the optical output of the optical module and the SOA current according to the present embodiment. FIG. 6 illustrates a case of the present embodiment in which the first optical isolator 16 and the second optical isolator 18 are present (“with the second optical isolator”) and a case where the second optical isolator 18 out of both optical isolators is absent (“without the second optical isolator”).

As illustrated in FIG. 6, in the present embodiment in which the first optical isolator 16 and the second optical isolator 18 are present in the entire range of the SOA current, the optical output is larger compared to the case where the second optical isolator 18 is absent. As described above, according to the present embodiment, the optical output of the optical module 10 can be improved, and the high optical output power can be obtained. In other words, according to the present embodiment, the same optical output power can be obtained by using a lower SOA current, and the power consumption of the optical module 10 can be reduced.

Further, FIG. 7 is a graph illustrating one example of a relationship between the polarization extinction ratio of the optical module 10 according to the present embodiment and the SOA current. As with FIG. 6, FIG. 7 illustrates the case of the present embodiment (“with the second optical isolator”) and the case where the second optical isolator 18 is absent (“without the second optical isolator”).

As illustrated in FIG. 7, without the second optical isolator 18, fluctuation in which the polarization extinction ratio of the optical module significantly increases or decreases due to a change in the SOA current is found, and the polarization extinction ratio is unstable. On the other hand, in the case of the present embodiment in which the first optical isolator 16 and the second optical isolator 18 are present, such fluctuation is not found in the polarization extinction ratio of the optical module 10, and the polarization extinction ratio is stable. As described above, according to the present embodiment, a stable polarization extinction ratio can be obtained.

As described above, according to the present embodiment, deterioration of the characteristics of the optical module 10 can be sufficiently suppressed, and high optical output power can be obtained.

### Second Embodiment

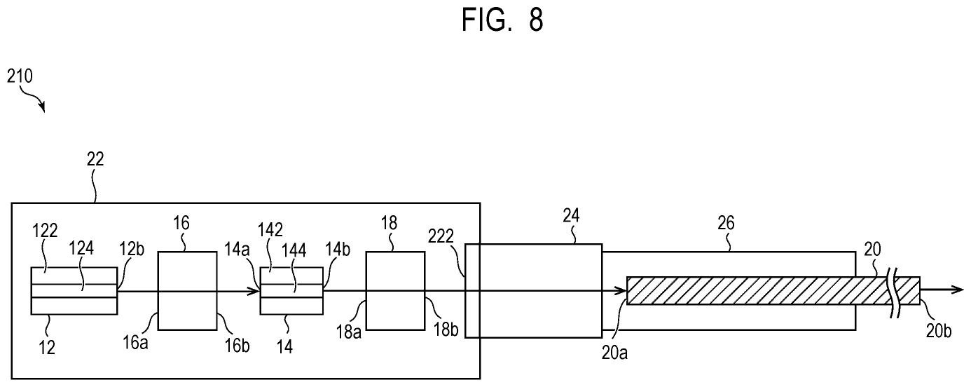

An optical module according to a second embodiment of the present invention will be described with reference to FIG. 8. FIG. 8 is a schematic diagram illustrating an optical module according to the present embodiment. Note that the same components as those in the optical module according to the first embodiment described above are labelled with the same reference, and the description thereof will be omitted or simplified.

The basic configuration of the optical module according to the present embodiment is substantially the same as the configuration of the optical module 10 according to the first embodiment. The optical module according to the present embodiment is different from the optical module 10 according to the first embodiment in the position where the second optical isolator 18 is arranged.

As illustrated in FIG. 8, in an optical module 210 according to the present embodiment, unlike the first embodiment, the second optical isolator 18 is not held in the holding member 24 and is accommodated in the package 22.

The second optical isolator 18 accommodated in the package 22 is arranged on the emission end 14b side of the SOA 14, that is, arranged between the emission end 14b of the SOA 14 and the entry end 20a of the optical fiber 20.

The second optical isolator 18 is not necessarily required to be arranged outside the package 22 as with the present embodiment and may be arranged inside the package 22.

### Third Embodiment

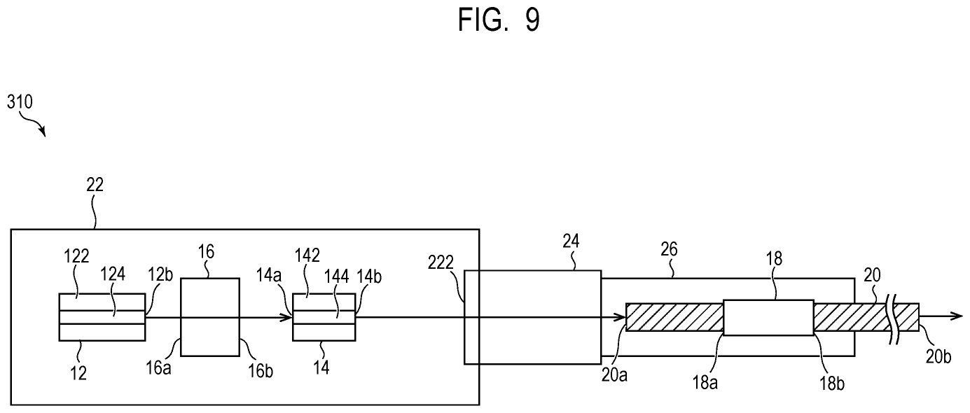

An optical module according to a third embodiment of the present invention will be described with reference to FIG. 9. FIG. 9 is a schematic diagram illustrating an optical module according to the present embodiment. Note that the same components as those in the optical modules according to the first and second embodiments described above are labelled with the same reference, and the description thereof will be omitted or simplified.

The basic configuration of the optical module according to the present embodiment is substantially the same as the configuration of the optical module 10 according to the first embodiment. The optical module according to the present embodiment is different from the optical module 10 according to the first embodiment in that the second optical isolator 18 is an in-line type optical isolator provided inside the optical fiber 20.

As illustrated in FIG. 9, in an optical module 310 according to the present embodiment, the second optical isolator 18 according to the first embodiment is an in-line type optical isolator provided in the middle of the optical fiber 20.

The in-line type second optical isolator 18 has the same function as the second optical isolator 18 according to the first embodiment. The in-line type second optical isolator 18 transmits a laser light in a fifth direction of entering the entry end 20a of the external optical fiber 20 from the emission end 14b of the SOA 14 and traveling toward the emission end 20b and blocks or attenuates a laser light in a sixth direction that is a direction opposite to the fifth direction. The in-line type second optical isolator 18 has the entry end 18a which a laser light entering the entry end 20a of the optical fiber 20 and traveling toward the emission end 20b of the optical fiber 20 enters and the emission end 18b that transmits and emits the laser light toward the emission end 20b of the optical fiber 20.

As with the first embodiment, the in-line type second optical isolator 18 provided in the optical fiber 20 is also able to block or attenuate a return light due to reflection, and deterioration of the characteristics of the SOA 14 can be suppressed. Note that the isolation of the in-line type second optical isolator 18 can also be set in the same manner as the second optical isolator 18.

As described in the present embodiment, the second optical isolator 18 may be an in-line type optical isolator provided in the optical fiber 20.

### Fourth Embodiment

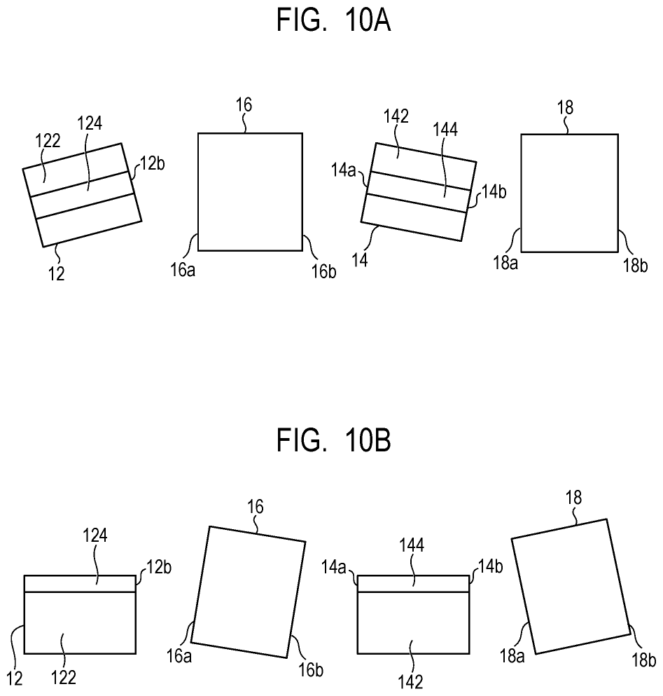

An optical module according to a fourth embodiment of the present invention will be described with reference to FIG. 10A and FIG. 10B. FIG. 10A and FIG. 10B are schematic diagrams illustrating arrangement of devices in an optical module according to the present embodiment. Note that the same components as those in the optical modules according to the first to third embodiments described above are labelled with the same reference, and the description thereof will be omitted or simplified.

In the first to third embodiments described above, the first optical isolator 16 and the second optical isolator 18 can be arranged so as to be tilted. Thereby, it is possible to prevent a return light due to reflection on the end face of the entry end 16a of the first optical isolator 16 from entering the semiconductor laser device 12 or prevent a return light due to reflection on the end face of the entry end 18a of the second optical isolator 18 from entering the SOA 14. In the present embodiment, a case where the first optical isolator 16 and the second optical isolator 18 are arranged so as to be tilted will be described in detail.

FIG. 10A is a plan view when the semiconductor laser device 12, the first optical isolator 16, the SOA 14, and the second optical isolator 18 arranged in the optical module 10 are viewed downward from the arrangement face on which these devices are arranged. FIG. 10B is a side view when the semiconductor laser device 12, the first optical isolator 16, the SOA 14, and the second optical isolator 18 arranged in the optical module 10 are viewed from the side of the arrangement face on which these devices are arranged.

As illustrated in FIG. 10A and FIG. 10B, the first optical isolator 16 is arranged so as to be tilted relatively to the semiconductor laser device 12. That is, the first optical isolator 16 is arranged so as to be tilted such that the entry direction of a laser light from the semiconductor laser device 12 to the end face of the entry end 16a of the first optical isolator 16 is tilted with respect to the normal direction of the end face of the entry end 16a of the first optical isolator 16.

With the first optical isolator 16 being arranged so as to be tilted in such a way, it is possible to suppress a return light due to reflection on the end face of the entry end 16a of the first optical isolator 16 from entering the semiconductor laser device 12. Thereby, deterioration of the characteristics of the semiconductor laser device 12 can be further suppressed.

Further, as illustrated in FIG. 10A and FIG. 10B, the second optical isolator 18 is arranged so as to be tilted relatively to the SOA 14. That is, the second optical isolator is arranged so as to be tilted such that the entry direction of an amplified laser light from the SOA 14 to the end face of the entry end 18a of the second optical isolator 18 is tilted with respect to the normal direction of the end face of the entry end 18a of the second optical isolator 18.

With the second optical isolator 18 being arranged so as to be tilted in such a way, it is possible to suppress a return light due to reflection on the end face of the entry end 18a of the second optical isolator 18 from entering the SOA 14. Thereby, deterioration of the characteristics of the SOA 14 can be further suppressed.

Note that, also in the second and third embodiments, the first optical isolator 16 and the second optical isolator 18 can be arranged so as to be tilted as with the present embodiment.

### Fifth Embodiment

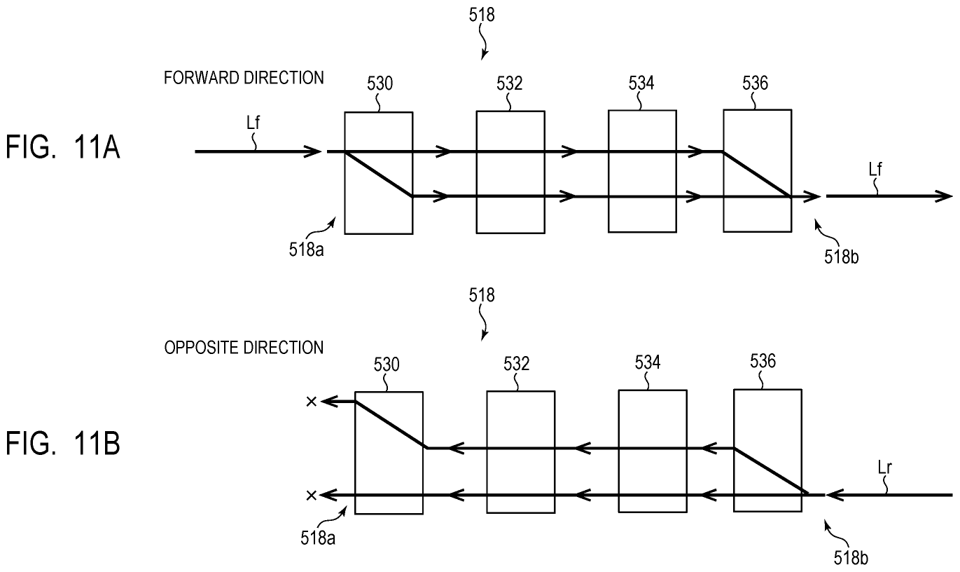

An optical module according to a fifth embodiment of the present invention will be described with reference to FIG. 11A and FIG. 11B. FIG. 11A and FIG. 11B are schematic diagrams illustrating a polarization independent optical isolator used for an optical module according to the present embodiment. Note that the same components as those in the optical modules according to the first to fourth embodiments described above are labelled with the same reference, and the description thereof will be omitted or simplified.

In the first to fourth embodiments described above, there may be a case where a polarization state of a return light that returns to an optical module is not constant, for example, such as a case of a reflected light on the end face of a connector or the like. In such a case, in the first to fourth embodiments, a polarization independent optical isolator can be used instead of the polarization dependent first and second optical isolators 16 and 18. In the present embodiment, a case where a polarization independent optical isolator is used instead of the polarization dependent second optical isolator 18 will be described.

As illustrated in FIG. 11A and FIG. 11B, a polarization independent optical isolator 518 has a birefringent crystal 530, a Faraday element 532, a half-wavelength plate 534, and a birefringent crystal 536. The birefringent crystal 530, the Faraday element 532, the half-wavelength plate 534, and the birefringent crystal 536 are aligned in this order from an entry end 518a side toward an emission end 518b side of an optical isolator 518. Note that FIG. 11A illustrates a case where a light Lf in the forward direction enters the entry end 518a with respect to the polarization independent optical isolator 518. Further, FIG. 11B illustrates a case where a light Lr in the direction opposite to the light Lf enters the emission end 518b with respect to the polarization independent optical isolator 518.

As illustrated in FIG. 11A, when entering the birefringent crystal 530 from the entry end 518a, the light Lf in the forward direction is split into two light beams of an ordinary beam and an extraordinary beam. The polarization of the two light beams split by the birefringent crystal 530 is sequentially rotated by the Faraday element 532 and the half-wavelength plate 534, and thereby the ordinary beam and the extraordinary beam are interchanged with each other and enter the birefringent crystal 536. As a result, the two light beams that sequentially transmit through the Faraday element 532 and the half-wavelength plate 534 and enter the birefringent crystal 536 are combined by the birefringent crystal 536 and are emitted from the emission end 518b as the light Lf in the forward direction.

On the other hand, as illustrated in FIG. 11B, when entering the birefringent crystal 536 from the emission end 518b, the light Lr in the opposite direction is split into two light beams of an ordinary beam and an extraordinary beam. While the polarization of the two light beams split by the birefringent crystal 536 is sequentially rotated by the half-wavelength plate 534 and the Faraday element 532, the Faraday element 532 rotates the polarization in the same direction regardless of the light entry direction. Therefore, the two light beams that transmit through the half-wavelength plate 534 and the Faraday element 532 in this order and enter the birefringent crystal 530 are not combined in the birefringent crystal 530 and prevented from being emitted from the entry end 518a because of absorption into the casing of the optical isolator 518 (not illustrated) or the like.

The polarization independent optical isolator 518 described above can be used instead of the second optical isolator 18 in the first to fourth embodiments.

Note that it is also possible to use the same polarization independent optical isolator as described above instead of the first optical isolator 16 in the first to fourth embodiments.

### Sixth Embodiment

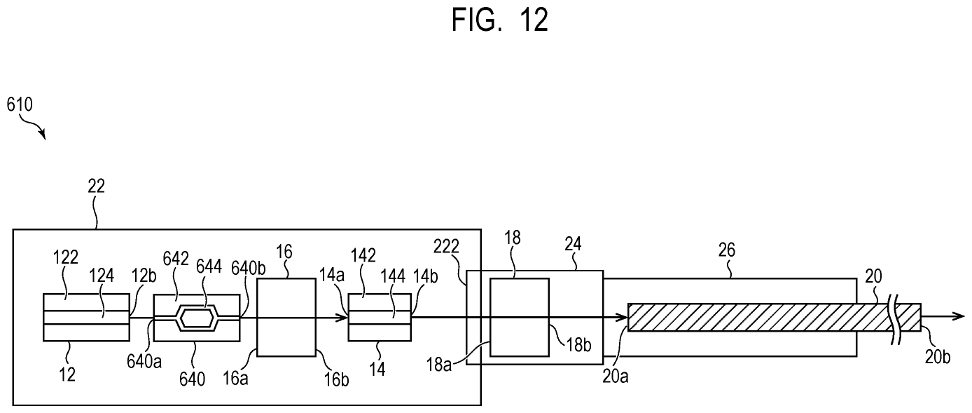

An optical module according to a sixth embodiment of the present invention will be described with reference to FIG. 12. FIG. 12 is a schematic diagram illustrating an optical module according to the present embodiment. Note that the same components as those in the optical modules according to the first to fifth embodiments described above are labelled with the same reference, and the description thereof will be omitted or simplified.

In the optical modules according to the first to fifth embodiments described above, an optical modulator used for modulating the laser light may be provided to the semiconductor laser device 12. In the present embodiment, a case where an optical modulator is provided in the first embodiment will be described.

As illustrated in FIG. 12, an optical module 610 according to the present embodiment further has an optical modulator 640 in addition to the configuration of the optical module 10 according to the first embodiment. The optical modulator 640 is accommodated in the package 22. Further, the optical modulator 640 is arranged between the emission end 12b of the semiconductor laser device 12 and the entry end 16a of the first optical isolator 16.

The optical modulator 640 has an entry end 640a and an emission end 640b and is arranged such that a laser light emitted from the emission end 12b of the semiconductor laser device 12 enters the entry end 640a. The optical modulator 640 functions as an optical modulation device that modulates a laser light that has entered the entry end 640a and emits the modulated laser light from the emission end 640b. The first optical isolator 16 is arranged such that the laser light modulated by the optical modulator 640 enters the entry end 16a.

The optical modulator 640 has a substrate 642 and an optical waveguide 644 having an optical modulation function such as a Mach-Zehnder optical waveguide formed on the substrate 642, for example. The modulation scheme of the optical modulator 640 is not particularly limited, and an intensity modulation, a phase modulation, or the like is performed on a laser light, for example.

Further, the optical modulator 640 may be monolithically provided on the same substrate as a substrate on which the semiconductor laser device 12 is provided or may be provided separately from the semiconductor laser device 12.

As illustrated in the present embodiment, the optical module 610 may further have the optical modulator 640. Note that, also in the second to fifth embodiments, it is possible to provide the optical modulator 640 in the same manner as described above.

### Modified Embodiment

The present invention is not limited to the embodiments described above, and various modifications are possible.

While the case where the semiconductor laser device 12 is used as a first optical function device has been described in the above embodiments, for example, the first optical function device is not limited thereto. The first optical function device may be any device having an optical function that may be affected by a return light due to reflection or the like or an ASE light. The first optical function device may be a light emitting device such as a light emitting diode device in addition to the semiconductor laser device. Further, the first optical function device is not limited to a light emitting device and may be an optical waveguide such as a planar lightwave circuit (PLC), an optical modulator, an optical mixer, or the like.

Further, while the case where the SOA 14 is used as a second optical function device has been described in the above embodiments, the second optical function device is not limited thereto. The second optical function device may be any device having a function that may be affected by a return light due to reflection or the like and amplifies and emits the received light.

### LIST OF REFERENCE NUMERALS

10, 210, 310, 610: optical module
12: semiconductor laser device
14: SOA
16: first optical isolator
18: second optical isolator
20: optical fiber
22: package
24: holding member
26: tubular member

1. An optical module comprising:
a first optical function device that has an emission end and emits a light from the emission end;
a second optical function device that has an entry end and an emission end, amplifies the light entering the entry end, and emits the amplified light from the emission end, wherein the light is emitted from the emission end of the first optical function device and enters the entry end;
a first optical non-reciprocal device that is arranged between the emission end of the first optical function device and the entry end of the second optical function device, transmits a light in a first direction from the emission end of the first optical function device toward the entry end of the second optical function device, and blocks or attenuates a light in a second direction that is a direction opposite to the first direction; and
a second optical non-reciprocal device that is arranged on the emission end side of the second optical function device, transmits a light in a third direction outward from the emission end of the second optical function device, and blocks or attenuates a light in a fourth direction that is a direction opposite to the third direction.

2. The optical module according to claim 1 further comprising an optical fiber optically connected to the emission end of the second optical function device.

3. The optical module according to claim 2, wherein the optical fiber is a polarization maintaining optical fiber or a single-mode optical fiber.

4. The optical module according to claim 1, wherein the first optical function device is a light emitting device.

5. The optical module according to claim 4, wherein the first optical function device is a semiconductor laser.

6. The optical module according to claim 4 further comprising an optical modulation device that modulates the light emitted from the emission end of the first optical function device.

7. The optical module according to claim 1, wherein the second optical function device is a semiconductor optical amplifier.

8. The optical module according to claim 1,
wherein the first optical non-reciprocal device is a first optical isolator, and
wherein the second optical non-reciprocal device is a second optical isolator.

9. The optical module according to claim 8, wherein the first optical isolator has isolation that is higher than or equal to 20 dB.

10. The optical module according to claim 8, wherein the second optical isolator has isolation that is higher than or equal to 15 dB.

11. The optical module according to claim 10, wherein the second optical isolator has isolation that is higher than or equal to 30 dB.

12. The optical module according to claim 1 further comprising a casing that accommodates the first optical function device and the second optical function device,
wherein the casing has a casing that accommodates at least the first optical non-reciprocal device.

13. The optical module according to claim 12, wherein the casing accommodates the first optical non-reciprocal device and the second optical non-reciprocal device.

14. The optical module according to claim 12,
wherein the casing accommodates the first optical non-reciprocal device,
the optical module further comprising another casing that accommodates the second optical non-reciprocal device.

15. The optical module according to claim 12,
wherein the casing accommodates the first optical non-reciprocal device, and
wherein the second optical non-reciprocal device is provided to an optical fiber which the light emitted from the emission end of the second optical function device enters.

16. The optical module according to claim 1,
wherein the first optical non-reciprocal device has an entry end which the light emitted from the emission end of the first optical function device enters, and
wherein the first optical non-reciprocal device is arranged such that an entry direction of the light to an end face of the entry end of the first optical non-reciprocal device is tilted with respect to a normal direction of the end face of the entry end of the first optical non-reciprocal device.

17. The optical module according to claim 1,
wherein the second optical non-reciprocal device has an entry end which the light emitted from the emission end of the second optical function device enters, and
wherein the second optical non-reciprocal device is arranged such that an entry direction of the light to an end face of the entry end of the second optical non-reciprocal device is tilted with respect to a normal direction of the end face of the entry end of the second optical non-reciprocal device.
